(19) United States
(12) Patent Application Publication
(10) Pub. No.: US 2023/0260742 A1
(43) Pub. Date: Aug. 17, 2023

(54) Open type RPS block device

(71) Applicants: Hea Keun YUN, Hwaseong-si (KR); Changwoo SHIN, Suwon-si (KR); Kang Yeol SEO, Suwon-si (KR)

(72) Inventors: Hea Keun YUN, Hwaseong-si (KR); Changwoo SHIN, Suwon-si (KR); Kang Yeol SEO, Suwon-si (KR)

(21) Appl. No.: 17/870,729

(22) Filed: Jul. 21, 2022

(30) Foreign Application Priority Data
Feb. 15, 2022 (KR) 10-2022-0019829

(51) Int. Cl. H01J 37/22; H01J 37/32

(52) U.S. Cl. CPC H01J 37/226; H01J 37/32449

(57) ABSTRACT

The present disclosure relates to a technology of using coating rather than existing so-called anodizing to perform surface treatment on the inner wall of a channel in an RPS block device. The present disclosure is a technology that implements a bentinternal channel of an RPS block device in an open type and implements a pattern of fastening the RPS block device after coating the wall of the open internal channel, thereby being able to coat even the bent internal channel of the RPS block device with a specific substance (e.g., yttrium). Further, the present disclosure is a structure that can be effectively maintained at a high temperature (e.g., 1300° C.) by inserting a heater.

### BACKGROUND OF THE INVENTION

### Field of the Invention

The present disclosure relates to a technology of using coating rather than existing anodizing to perform surface treatment on the inner wall of an internal passage of a remote plasma source (RPS) block device.

In more detail, the present disclosure is a technology that implements a bent internal passage of an RPS block device in an open type and implements a pattern of fastening the RPS block device after coating the wall of the open internal passage, thereby being able to coat even the bent internal passage of the RPS block device with a specific substance (e.g., yttrium).

In particular, the present disclosure is a structure that can be effectively maintained at a high temperature (e.g., 1300° C.) by inserting a heater.

### Description of the Related Art

FIG. 1 is an exemplary view showing a use state of a common RPS device. Referring to FIG. 1, the RPS device is, for example, disposed close to a process chamber and monitors process gases that is discharged from the process chamber.

To this end, the common RPS device 10 is formed in a block shape with an open internal passage. An inlet 11 as a passage that is connected to a process chamber may be formed at an end of the RPS block device 10 and one or more outlets 12 and 13 for discharging process gases flowing in the body thereof may be formed on a side of the RPS block device 10. A connection passage 14 for connecting the inlet 11 to the outlets 12 and 13 may be positioned at a portion bending from the inlet 11 or the outlets 12 and 13.

The RPS block device 10 functions as a passage for moving plasma and process gases (e.g., NF₃) that are discharged from a process chamber. Surface treatment is performed to protect the inner wall of the passage of the RPS block device from a chemical reaction of the plasma and the process gas, and anodizing is usually applied.

Since anodizing induces a chemical reaction through a process of submerging the RPS block device 10 into a treatment solution, it is possible to apply surface treatment to the entire inner wall of the internal passage of the RPS block device 10 without omission even when the internal passage has a bent pattern.

However, anodizing surface treatment has a problem that the inner wall of the passage of the RPS block device 10 is not protected due to corrosion when it is exposed for a long time to plasma and process gases that are discharged from a process chamber.

There is also an additional problem that particles produced by corrosion in the internal passage of the RPS block device 10 become contaminants in a semiconductor production process and decrease the yield ratio of semiconductors.

### SUMMARY OF THE INVENTION

An objective of the present disclosure is to provide an open type RPS block device in which the inner wall of the body thereof can be coated with a specific substance to be able to be protected even from a chemical reaction of plasma and process gases that are discharged from a process chamber.

In order to achieve the objectives, an open type RPS block device according to the present disclosure includes: an RPS body 110 having an inlet 111 that receives process gases, a first outlet 112 that discharges the process gas received through the inlet, a second outlet 113 that discharges the process gas received through the inlet, and a body connection path 114 that connects the inlet, the first outlet, and the second outlet to each other in the body and is open at a side in a longitudinal direction of a body thereof; an RPS cover 120 having an open-type connection path 121 that is open on a side at a position where the side faces the body connection path and is coupled in contact with a side of the RPS body such that a hollow channel is formed by a side boundary of the body connection path and a side boundary of the open-type connection path that are in contact with each other; an inner wall coating forming a coating layer on an inner wall of the channel formed by the body connection path and the open-type connection path; a heater rod 180 inserted in the RPS body and heating the RPS body; a temperature sensor 190 mounted on any one or more of the RPS body and the RPS cover to sense temperature at the position; and an RPS controller controlling operation of the heater rod on the basis of temperature information obtained by the temperature sensor.

The open type RPS block device may further include a hermetic O-ring 140 disposed on the interface between the RPS body and the RPS cover to keep the portion between the RPS body and the RPS cover hermetic.

The RPS cover 120 may have a connection hole 122 formed to the RPS cover to be connected with the open-type connection path from an outer surface thereof.

The open type RPS block device may further include a transparent plate 150 coupled to a connection hole and made of a transparent material so that the open-type connection path can be visually seen from the outside of the RPS cover.

The open type RPS block device may further include: a fixing block 160 having a hollow hole formed through the center thereof and coupled to the connection hole in parallel with the transparent plate such that the hollow hole is connected with the open-type connection path, thereby fixing the transparent plate to the connection hole of the RPS cover; and an optical sensor 170 fitted in the hollow hole of the fixing block and sensing the degree of particles that stick to a surface of the transparent plate that corresponds to the open-type connection path.

### BRIEF DESCRIPTION OF THE DRAWINGS

FIG. 1 is an exemplary view showing a use state of a common RPS device;

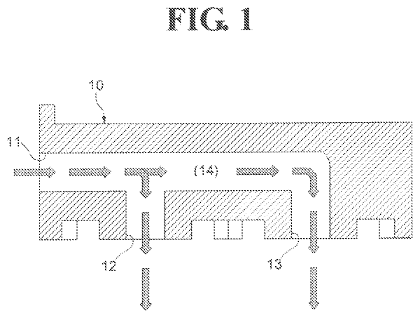

FIG. 2 is an exemplary view showing a process of coating the inner wall of a common RPS block device using a coating spray nozzle;

FIG. 3 is an exemplary view showing the external shape of an open type RPS block device according to the present disclosure;

FIG. 4 is a view showing the RPS block device shown in FIG. 3 at another angle;

FIG. 5 is a vertical cross-sectional view of an optical sensor shown in FIG. 3;

FIG. 6 is an exploded view of an RPS body and an RPS cover shown in FIG. 5;

FIG. 7 is an exploded view of components close to the RPS cover shown in FIG. 6;

FIG. 8 is an exploded view of some components shown in FIG. 3;

FIG. 9 is an enlarged view showing some components shown in FIG. 8;

FIG. 10 is an exploded view of some components shown in FIG. 4; and

FIG. 11 is an enlarged view showing some components shown in FIG. 10.

### DESCRIPTION OF EMBODIMENTS

Hereafter, the present disclosure is described in detail with reference to the drawings.

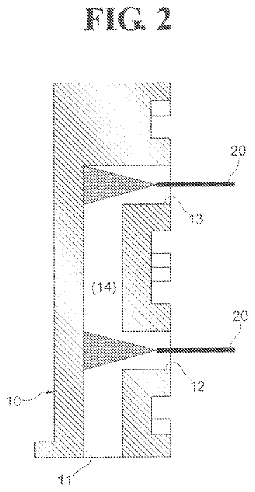

First, FIG. 2 is an exemplary view showing a process of coating the inner wall of a common RPS block device using a coating spray nozzle.

It should be noted that a specific substance is straightly sprayed from a coating spray nozzle 20 to coat the RPS block device 10. For example, as in FIG. 2, the coating spray nozzle 20 sprays a coating substance forward. However, since the internal passage of the RPS block device 10 is bent, the coating substance does not reach some section of the connection passage 14.

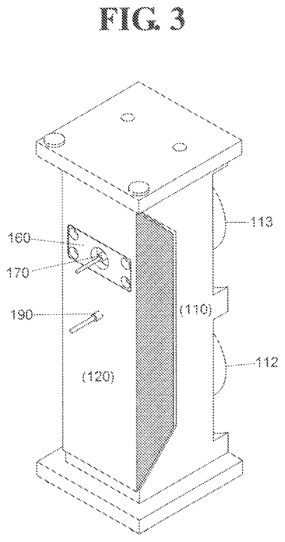

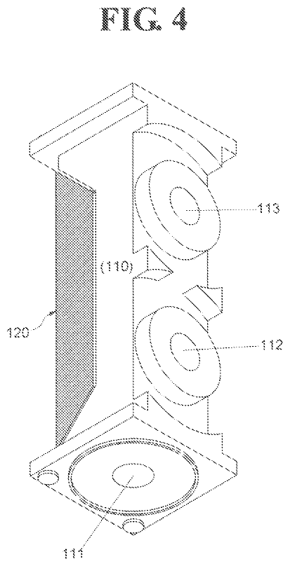

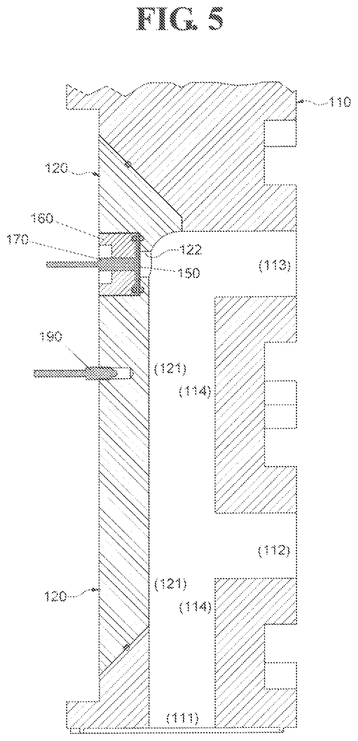

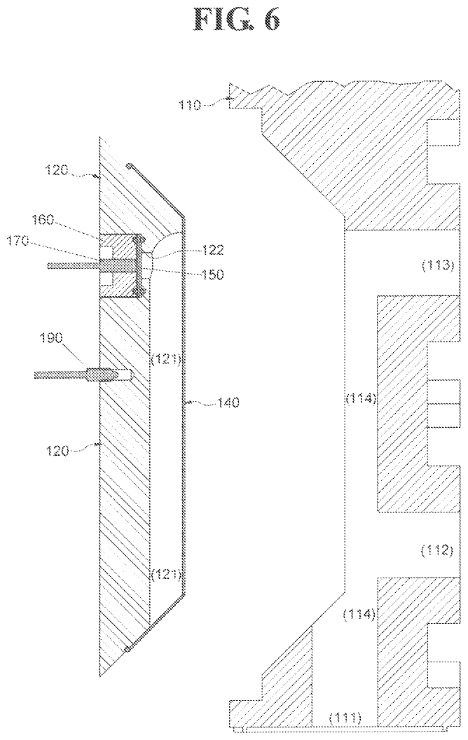

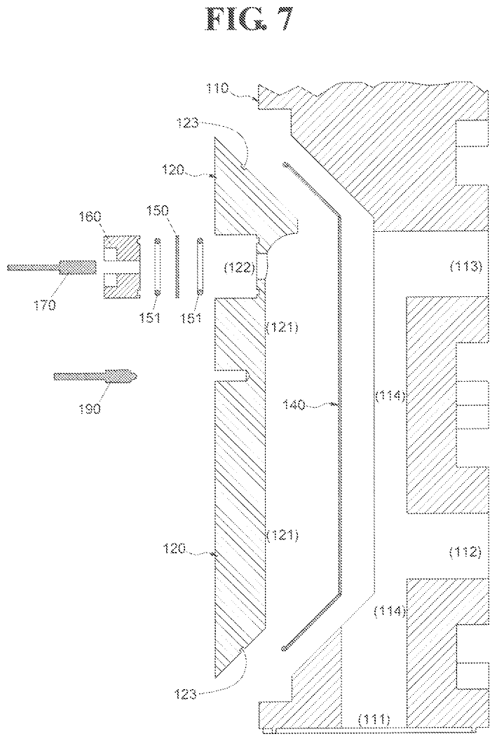

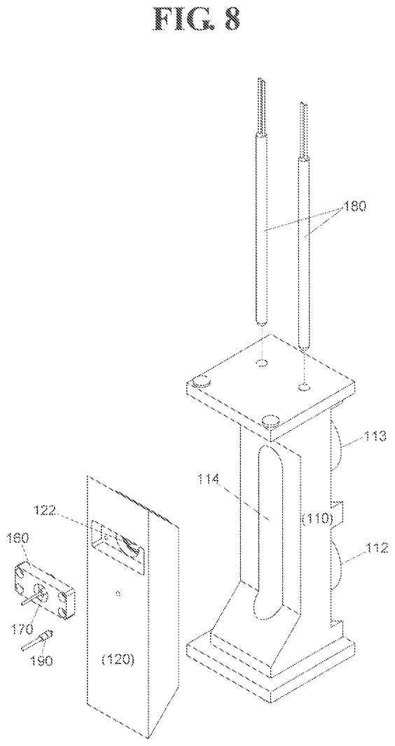

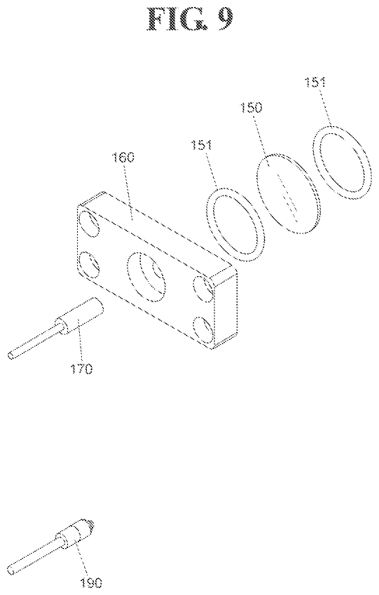

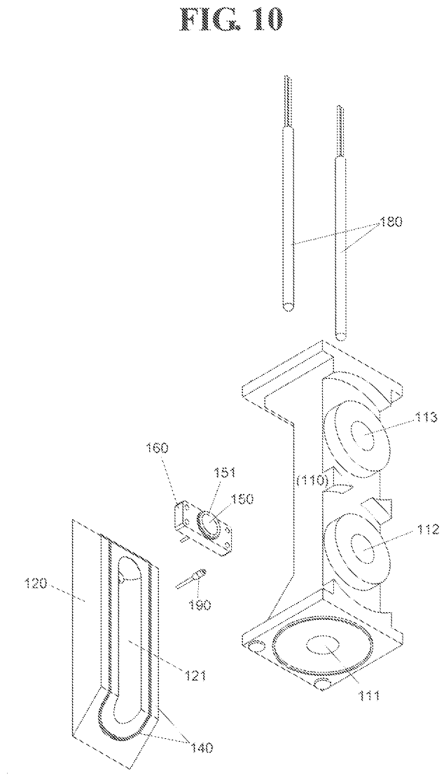

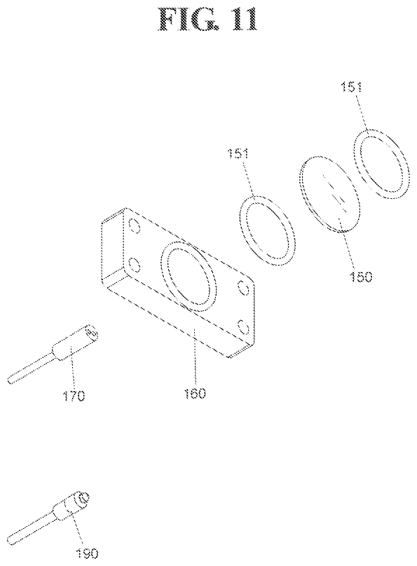

FIG. 3 is an exemplary view showing the external shape of an open type RPS block device according to the present disclosure, FIG. 4 is a view showing the RPS block device shown in FIG. 3 at another angle, FIG. 5 is a vertical cross-sectional view of an optical sensor shown in FIG. 3, FIG. 6 is an exploded view of an RPS body and an RPS cover shown in FIG. 5, FIG. 7 is an exploded view of components close to the RPS cover shown in FIG. 6, FIG. 8 is an exploded view of some components shown in FIG. 3, FIG. 9 is an enlarged view showing some components shown in FIG. 8, FIG. 10 is an exploded view of some components shown in FIG. 4, and FIG. 11 is an enlarged view showing some components shown in FIG. 10.

The open type RPS block device according to the present disclosure may include an RPS body 110, an RPS cover 120, an inner wall coating, a heater rod 180, a temperature sensor 190, and an RPS controller (not shown).

The RPS body 110 is formed in a block shape with a bentinternal passage and may have an inlet 111, one or more outlets 112 and 113, and a body connection path 114.

The inlet 111 is an inlet of the passage formed through the body from an end of the RPS body 110. In general, the inlet 111 is connected to a process chamber to receive process gases and plasma into the RPS body 110.

The first outlet 112 is coupled to an external connection pipe, thereby providing a passage for discharging fluid in the RPS body 110 to the outside.

The second outlet 113 is also coupled to an external connection pipe, thereby providing a passage for discharging fluid in the RPS body 110 to the outside in cooperation with the first outlet 112.

The body connection path 114 connects the inlet 111, the first outlet 112, and the second outlet 113 to each other in the RPS body 110. The body connection path 114 may be formed to be open at a side in the longitudinal direction of the RPS body 110.

The RPS cover 120 may be formed in a block shape having a passage in the body thereof and may have an open-type connection path 121.

The open-type connection path 121 is open on a side at a position where the side faces the body connection path 114. The RPS cover 120 may be coupled in contact with a side of the RPS body 110 such that a hollow channel is formed by a side boundary of the body connection path 114 and a side boundary of the open-type connection path 121 that are in contact with each other.

An inner wall coating is a coating layer that is formed on the inner wall of the hollow channel formed by the body connection path 114 and the open-type connection path 121. For example, the inner wall coating (not shown) may be formed by spraying a coating substance (e.g., yttrium) from a coating nozzle.

The inner wall coating protects the inner wall of the passage of the RPS block device from an external chemical reaction (e.g., a chemical reaction of plasma and process gases) such that durability can be maintained.

The heater rod 180, as shown in FIGS. 8 and 10, is inserted in the RPS body 110 and heats the RPS body 110, thereby being able to maintain the RPS body 110 at a high temperature (e.g., 1300° C.). Preferably, particles do not stick to the inner wall of the RPS block device only when the RPS block device is maintained at a high temperature over about 1300° C.

Meanwhile, the RPS block device may have a specific cooling fin to control a continuous increase of temperature due to plasma flowing in the RPS block device in a process of operating the RPS block device. When the cooling fin stops operating and the process is finished, the temperature of the RPS block device drops. The heater rod 180 is provided since it is required to heat the RPS block device to increase the temperature again as necessary.

The operation of the heater rod 180 may be controlled by the RPS controller, and the RPS controller may be configured to control the operation of the heater rod 180 on the basis of information collected from the temperature sensor 190.

The temperature sensor may be mounted on any one or more of the RPS body 110 and the RPS cover 120 to sense temperature at the position. The RPS controller may be configured to control the operation of the heater rod 180 on the basis of temperature information obtained by the temperature sensor 190.

The open type RPS block device according to the present disclosure may further include a hermetic O-ring 140, a transparent plate 150, a fixing block 160, and an optical sensor 170.

The hermetic O-ring 14 may be disposed on the interface between the RPS body 110 and the RPS cover 120 to keep the portion between the RPS body 110 and the RPS cover 120 hermetic. A slit 123 may be formed with a predetermined depth on a surface of the RPS cover 120 that faces the RPS body 110 so that the hermetic O-ring 140 can be fixed.

The transparent plate 150 is coupled to a connection hole 122 and may be made of a transparent material so that the open-type connection path 121 can be visually seen from the outside of the RPS cover 120. To this end, the RPS cover 120 may have the connection hole 122 formed to the RPS cover 120 to be connected with the open-type connection path 121 from the outer surface thereof.

The fixing block 160 has a hollow hole formed through the center thereof and may be coupled to the connection hole 122 in parallel with the transparent plate 150 such that the hollow hole is connected with the open-type connection path 121. Accordingly, the fixing block 160 can stably fix the transparent plate 150 to the connection hole 122 of the RPS cover 120.

The optical sensor 170 may be fitted in the hollow hole of the fixing block 160. The optical sensor 170 may be configured to sense the degree of particles that stick to a surface of the transparent plate 150 that corresponds to the open-type connection path 121.

To this end, the optical sensor 170 may include a light emitter and a light collector. For example, a light emitter may be configured to emit light toward the RPS body 110 from a surface of the transparent plate 150. Further, a light collector may be configured to collect reflective light emitted from the light emitter and then returning after hitting against the transparent plate 150. If the amount of reflective light that is collected by the light collector is small, it means that the transparent plate 150 is relatively less contaminated, that is, a large amount of light emitted from the light emitter passed through the transparent plate 150. However, if the amount of reflective light that is collected by the light collector is large, it means that the transparent plate 150 is relatively much contaminated, that is, a large amount of light emitted from the light emitter is reflected without passing through the cloudy surface of the transparent plate 150.

Meanwhile, the operation of the optical sensor 170 may be controlled by the RPS controller, and when information collected from the optical sensor 170 is transmitted to the RPS controller, the RPS controller can collect and analyze the information.

Meanwhile, since an O-ring 151 is disposed on a surface of the transparent plate 150 disposed on the rear surface of the fixing block 160, it is possible to keep the portion between the surface of the transparent plate 150 and the fixing block 160 hermetic. An O-ring 150 may be disposed also on the other surface of the transparent plate 150 to keep the portion between the surface of the transparent plate 150 and the RPS body 110 hermetic.

According to the present disclosure, there is an advantage that it is possible to coat the inner wall of the RPS block device with a specific substance.

Further, according to the present disclosure, there is an advantage that it is possible to visually determine the degree of contamination in the RPS block device.

Further, according to the present disclosure, there is an advantage that it is possible to maintain a high temperature (e.g., 1300° C.) by inserting a heater.

While the present invention has been described with respect to the specific embodiments, it will be apparent to those skilled in the art that various changes and modifications may be made without departing from the spirit and scope of the invention as defined in the following claims.

What is claimed is:

1. An open type RPS block device, comprising:
an RPS body having an inlet that receives process gases, a first outlet that discharges the process gas received through the inlet, a second outlet that discharges the process gas received through the inlet, and a body connection path that connects the inlet, the first outlet, and the second outlet to each other in the body and is open at a side in a longitudinal direction of a body thereof;
an RPS cover having an open-type connection path that is open on a side at a position where the side faces the body connection path and is coupled in contact with a side of the RPS body such that a hollow channel is formed by a side boundary of the body connection path and a side boundary of the open-type connection path that are in contact with each other;
an inner wall coating forming a coating layer on an inner wall of the channel formed by the body connection path and the open-type connection path;
a heater rod inserted in the RPS body and heating the RPS body;
a temperature sensor mounted on any one or more of the RPS body and the RPS cover to sense temperature at the position; and
an RPS controller controlling operation of the heater rod on the basis of temperature information obtained by the temperature sensor.

2. The open type RPS block device of claim 1, further comprising:
a hermetic O-ring disposed on the interface between the RPS body and the RPS cover to keep the portion between the RPS body and the RPS cover hermetic.

3. The open type RPS block device of claim 2, wherein
the RPS cover has a connection hole formed to the RPS cover to be connected with the open-type connection path from an outer surface thereof, and
the open type RPS block device further comprises:
a transparent plate coupled to a connection hole and made of a transparent material so that the open-type connection path can be visually seen from the outside of the RPS cover.

4. The open type RPS block device of claim 3, further comprising:
a fixing block having a hollow hole formed through the center thereof and coupled to the connection hole in parallel with the transparent plate such that the hollow hole is connected with the open-type connection path, thereby fixing the transparent plate to the connection hole of the RPS cover; and
an optical sensor fitted in the hollow hole of the fixing block and sensing the degree of particles that stick to a surface of the transparent plate that corresponds to the open-type connection path.
